(19) United States
(12) Patent Application Publication
(10) Pub. No.: US 2005/0021421 A1
(43) Pub. Date: Jan. 27, 2005

(54) Electrical media replaying device

(76) Inventor: Dave Herman, North Canton, OH (US)

Correspondence Address: Timothy D. Smith;Brouse McDowell, LPA, Ste. 500, 106 S. Main Street, Akron, OH, 44308-1471, US

(21) Appl. No.: 10/898,296

(22) Filed: Jul. 23, 2004

Related U.S. Application Data
(60) Provisional application No. 60/489,821, filed on Jul. 24, 2003.

(51) Int. Cl. G06F 17/60; G11C 5/00; G10H 7/00

(52) U.S. Cl. 705/26

(57) ABSTRACT

A stand alone console includes selector buttons and a joystick that that communicated to a computer logic controller stored within the stand alone console. A display is connected to the console and communicated to the logic controller to display lists of categorized, digitized music stored on a static digital storage device. A currency receiver is also included in the stand alone console and is communicated to the logic controller such that selection of the buttons and joystick and receipt of money generates a signal to play music through console speakers.

This patent application claims priority to U.S. Provisional patent application Ser. No. 60/489,821 filed on Jul. 24, 2003.

### 1. BACKGROUND OF THE INVENTION

A. Field of Invention

This invention pertains to the art of methods and apparatuses for entertainment devices, and more particularly to devices that selectively replay music.

B. Description of the Related Art

It is known in the art for an establishment, such as a food service establishment or other customer oriented activity establishment, to provide a jukebox for use in allowing the establishment's customers to selectively replay desired songs. Typically jukeboxes require the user to cycle through the entire selection of available songs to find a desired song or songs to replay. This usually includes cycling through every genre of music available from the play list; many of which the user may not be interested in. What is needed is a customer oriented device that can quickly and easily show the available selections to the user through the use of a joystick and genre buttons.

### II. SUMMARY OF THE INVENTION

According to one aspect of the present invention, a new and improved music replaying device is provided which incorporates a joystick for selecting a desired song to be replayed.

Another aspect of this invention is includes genre buttons that allow the user to focus on the type of music that the user favors.

Yet another aspect of this invention includes an electronic audio replaying device, comprising:
a stand alone console having a front face portion;
an electronic digital microprocessor operatively received within the console, the digital microprocessor being preprogrammed with an associated algorithm;
digital storage means for use in storing an associated plurality of digitized music according to one or more predetermined categories, the digital storage means being operatively communicated to the digital microprocessor; display screen operatively communicated to the digital microprocessor for use in displaying device replaying information, the electronic display being operatively received by the front face portion of the stand alone console;
one or more genre buttons operatively communicated to the digital microprocessor for use in receiving user input, wherein the one or more genre buttons correspond to the one or more predetermined categories respectively;
a joystick operatively communicated to the digital microprocessor for use in selecting one of the plurality of digitized music;
audio speakers operatively communicated to the digital storage means, wherein audio output transmitted from the digital storage means is controlled by the electronic digital microprocessor;
monetary receiving means for use in receiving associated money; the monetary receiving means being operatively communicated to the digital logic processor; and,
wherein the associated digitized music is transmitted through the audio output means responsive to receiving associated money by the monetary receiving means and to engaging the joystick.

Another aspect of the subject invention includes an electronic audio replaying device that includes:
a console;
an electronic digital logic processor operatively received by the console;
digital storage means for use in storing associated digitized audio media, the digital storage means being operatively communicated to the digital logic processor;
electronic display operatively communicated to the digital logic processor for use in displaying associated device replaying information, the electronic display being operatively received by the console;
user-interface operatively communicated to the digital logic processor for use in receiving user-input;
audio output means operatively communicated to the digital storage means;
monetary receiving means for use in receiving monetary units; the monetary receiving means being operatively communicated to the digital logic processor; and,
wherein the associated digitized audio media is transmitted through the audio output means responsive to the monetary receiving means and the user-interface.

Still another aspect of the subject invention includes a stand alone console.

Yet another aspect of the subject invention includes a stand alone console that has at least a first face portion, and,
wherein the electronic display and the user-interface means are operatively received by the at least a first face portion.

Another aspect of the subject invention includes user-interface or selector buttons, wherein the device replaying information is displayed responsive to the input by way of the one or more selector buttons.

Another aspect of the subject invention includes a joystick, wherein associated device replaying information is displayed responsive to the input by way of the joystick.

Still other benefits and advantages of the invention will become apparent to those skilled in the art to which it pertains upon a reading and understanding of the following detailed specification.

### III. BRIEF DESCRIPTION OF THE DRAWINGS

The invention may take physical form in certain parts and arrangement of parts, a preferred embodiment of which will be described in detail in this specification and illustrated in the accompanying drawings which form a part hereof and wherein:

FIG. 1 is a schematic representation of the subject invention.

FIG. 2 is a top view of the console showing the display and selectors devices.

FIG. 3 is a perspective view of the stand alone console.

FIG. 4 is a partial cutaway view of the console showing internal componentry.

### IV. DESCRIPTION OF THE PREFERRED EMBODIMENT

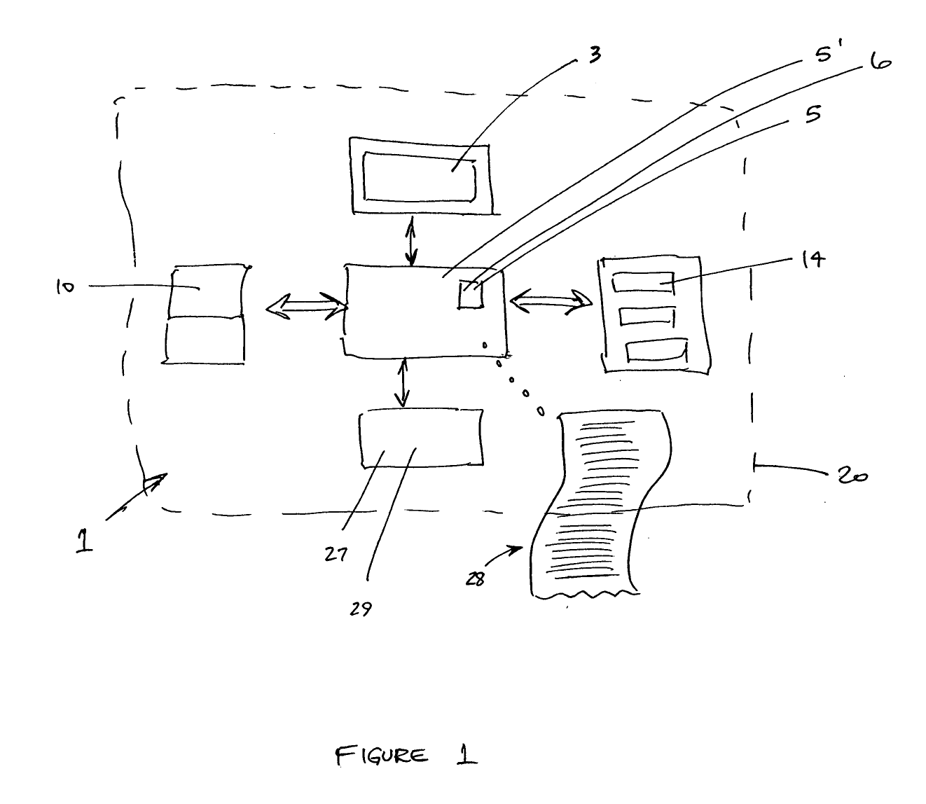

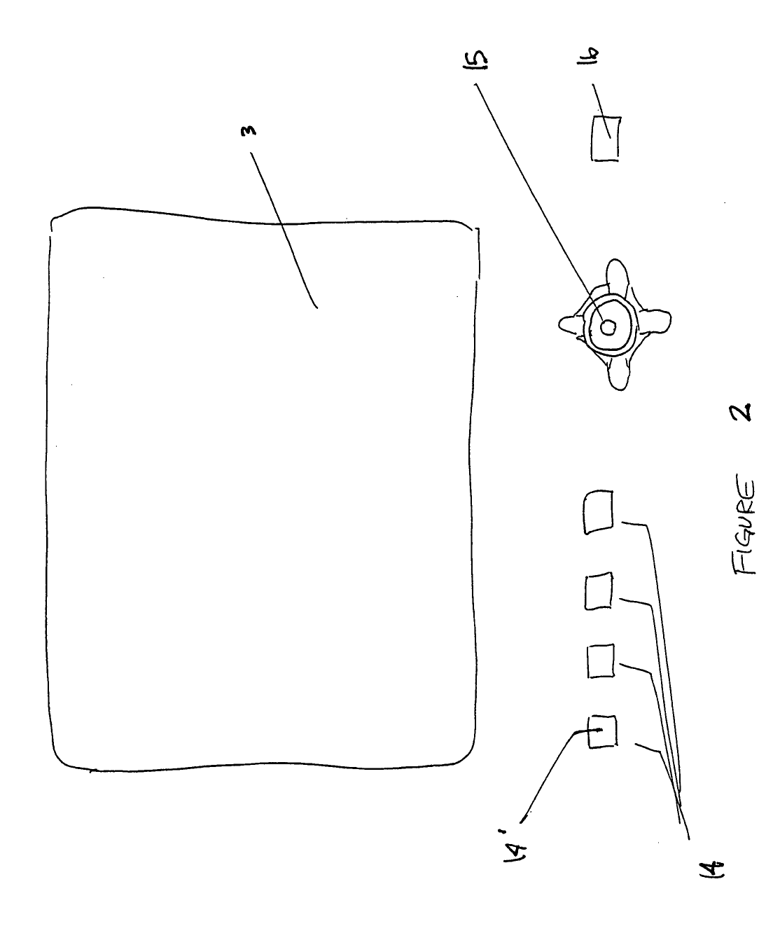

Referring now to the drawings wherein the showings are for purposes of illustrating a preferred embodiment of the invention only and not for purposes of limiting the same, FIGS. 1 and 2 show a schematic block diagram of a music replaying device 1. The music replaying device 1 may include a display monitor 3 that is electronically communicated to a CPU or logic processing device 5. In one embodiment, the CPU logic processing device may be a computer controller or computer 5′. The computer controller 5′ may include a microprocessor 6 and peripheral processing ICs 8 (Integrated Circuits) in a manner well known in the art. The music replaying device may also include a static digital storage device 10, such as a hard drive 10. Alternately, and/or in addition to, the music replaying device may include a CD-ROM 10′ or DVD 10″ wherein the CD-ROM/DVD 10′, 10″ includes hardware that is electronically communicated to the CPU logic processing device 5 and the display monitor or display screen 3. The music replaying device may further include selector buttons 14 for use in allowing the user to select the genre of music and for use in initiating play of the selected songs(s). It is noted that any means for facilitating the selection of the music genre and/or play of the music can be chosen with sound engineering judgment. That is to say, for example, that selector switches or the like could be incorporated for allowing the user to select the desired genre of music. Additionally, a joystick 17 may be incorporated into the music replaying device 1 that allows the user to quickly and easily cycle through the selection of available songs via the display screen.

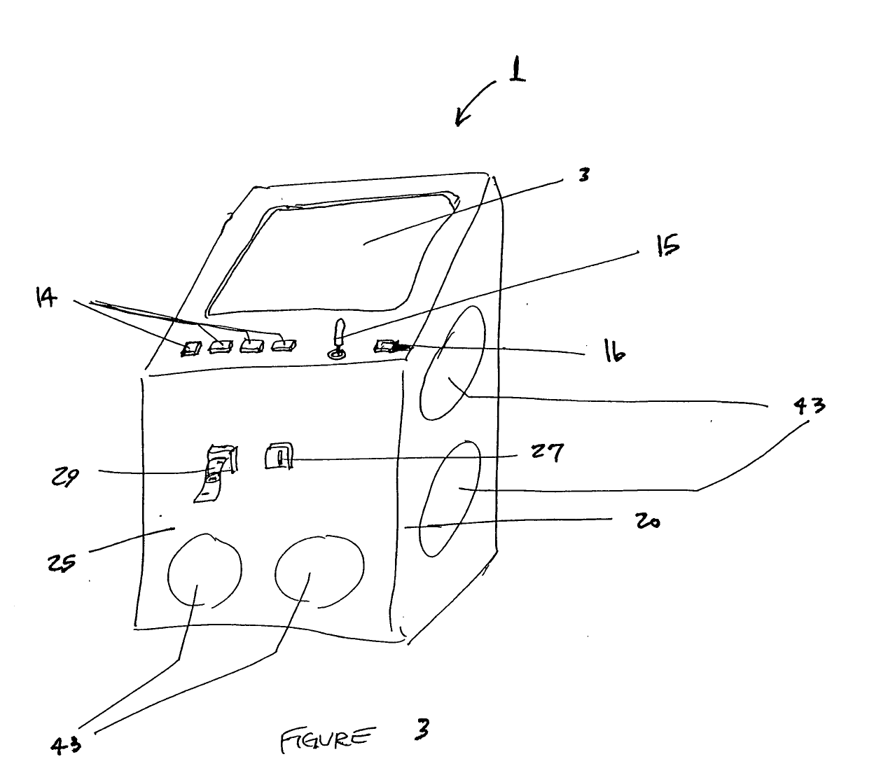

With reference now to FIG. 3, a music replaying device console 20 or console 20 is shown. The console 20 may include a frame or housing 21 that contains the components of the music replaying device 1. The console 20 may include a top face 22 that holds the display screen 3 at any conveniently chosen angle for easy viewing by the user. The selector genre buttons 14, play button 16 and joystick 15 may also be conveniently arranged anywhere about the surface of the face 22 of the console. It is noted that any configuration of positioning the buttons 14, 16 and joystick 15 may be chosen with sound engineering judgment. The console 20 may also include side panels. In one embodiment, the front side panel 25 may hold a coin 27 or currency receiver 29 for use in providing a means for the user to pay for using the music replaying device 1. The currency receiver 29 may be communicated to the computer controller 5′ so as to signal the computer controller 5′ when the user has inserted the appropriate amount of money to begin using the music replaying device 1. Any means of collecting monetary payment for use in utilizing the music replaying device 1 may be chosen with sound engineering judgment. In one embodiment, the computer controller 5′ may include an algorithm 28 that receives input and logically processes output responsive to the input. In that the programming of logic processors 5 and computers 5′ is well known in the art no further explanation will be offered at this time.

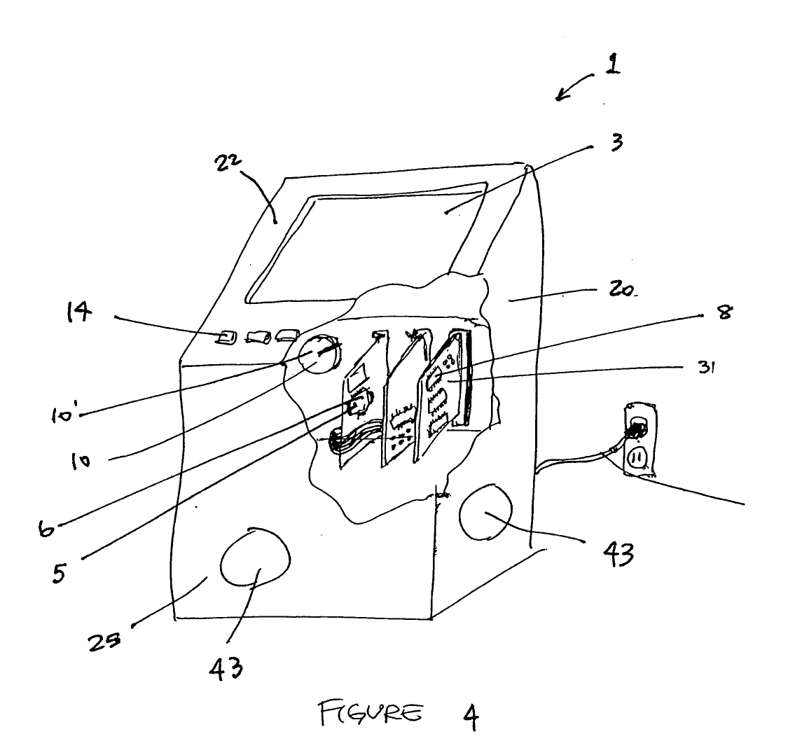

With continued reference to FIG. 3 and now to FIG. 4, the console 20 may comprise a housing 21 that contains the computer controller components. The computer controller 5′ may include a main processor board 31. The main processor board may further comprise a microprocessor 6 and peripheral support chips, such as RAM, ROM, etc., as well as data buses and the like. Since the use of microprocessors 6, computer memory, data highways and the like are well known in the art no further explanation will be offered at this time. The computer controller 5′ may control the storage and replaying of music that may be digitally stored on a hard drive 33, CD-ROM 34 or DVD 35. In this manner, music may be digitally, categorically stored in the computer controller components. Additionally, the categorically stored music may be stored, and selected, based upon the respective categories. For example, a song may be digitally stored on the hard-drive of the computer controller 5′. The song may also be stored with additional information about the song such as the type, or category, of music that the song resides in. The computer controller 5′ may facilitate the storage management of the songs and associated data. When the user of the music replaying device 1 engages the selector buttons 14, the input from the selector buttons 14 may signal the microprocessor 6 and/or the algorithm to display part or all of the songs that are digitally stored in the computer controller 5′ responsive to which selector button 14 was selected. In other words, the user may depress one selector button 14′ where after the display 3 may generate a list of songs based upon the selection of the button 14′. The play button 16 may subsequently be engaged to begin playing the song subject to the currency receiver 29 as will be discussed in a subsequent paragraph.

With continued reference to FIG. 3, the console may also incorporate music speakers 43 that may be internal to the console 20 and electrically communicated to the computer controller 5′ in any manner chosen with sound engineering judgment. Once a song has been initiated for display and play, the controller 5′ may begin playing the song through speakers 43 mounted in the housing of the stand alone console. Any number, quality and type of speakers may be chosen with sound engineering judgment as is appropriate for use the subject invention.

With continued reference to all of the FIGURES, the computer controller 5′ may be selectively programmable. That is to say that any programming means may be used to control the function of the computer controller 5′ for replaying the desired music. For example, the computer controller 5′ may be selectively programmed via a high level programming language, such as Visual Basic, C or the like. An associated programmer may construct code that controls the functions of the computer controller 5′ including but not limited to monitoring the currency receiver 29, displaying advertisements on the display screen 3, facilitating replay of the music through the console speakers 43, displaying the genre categories that the songs are listed by, and the like. It is noted that any function controlled by the computer controller 5′ may be programmed and controlled by the software incorporated therein. In this manner, the CPU logic processing device 5, including memory and additional circuitry, may store and run one or more algorithms 28 that display a message on the display screen 3 when the music replaying device is not currently playing music.

With reference to all of the Figures, the computer controller 5′ may be selectively programmed to interact with the selector buttons 14 and joystick 15 mounted on the top of the console 20. The computer controller 5′ may monitor input from the buttons 14 and joystick 15 and display music selections responsive to the input. As the user moves the joystick 15 in one direction, different available selections of music presently displayed on the screen may be highlighted to indicate the desired choice. When the user highlights the desired song, the user may then depress the play button 16 at which time the controller would retrieve the digitally stored song and replay the song through console speakers. In one embodiment, the user may deposit additional sums of money for replaying subsequent songs. In this way, the user may be prompted by the display screen to select another song for replaying after the present selection.

With reference now to FIGS. 1 and 2, the joystick 15 may be bi-directional joystick. In other words, the joystick may move in first and second directions for moving the highlighted musical selection up or down as desired. In an alternate embodiment, the joystick 15 may be quad-directional. However, any type or configuration of joystick may be chosen with sound engineering judgment as is appropriate for use the subject invention. It is noted that any other type of selection means or device may be used in place of the joystick as chosen with sound engineering judgment.

The preferred embodiments have been described, hereinabove. It will be apparent to those skilled in the art that the above methods may incorporate changes and modifications without departing from the general scope of this invention. It is intended to include all such modifications and alterations in so far as they come within the scope of the appended claims or the equivalents thereof.

1. An electronic audio replaying device, comprising:
a stand alone console having a front face portion;
an electronic digital microprocessor operatively received within the console, the digital microprocessor being preprogrammed with an associated algorithm;
digital storage means for use in storing an associated plurality of digitized music according to one or more predetermined categories, the digital storage means being operatively communicated to the digital microprocessor;
display screen operatively communicated to the digital microprocessor for use in displaying device replaying information, the electronic display being operatively received by the front face portion of the stand alone console;
one or more genre buttons operatively communicated to the digital microprocessor for use in receiving user input, wherein the one or more genre buttons correspond to the one or more predetermined categories respectively;
a joystick operatively communicated to the digital microprocessor for use in selecting one of the plurality of digitized music;
audio speakers operatively communicated to the digital storage means, wherein audio output transmitted from the digital storage means is controlled by the electronic digital microprocessor;
monetary receiving means for use in receiving associated money; the monetary receiving means being operatively communicated to the digital logic processor; and,
wherein the associated digitized music is transmitted through the audio output means responsive to receiving associated money by the monetary receiving means and to engaging the joystick.

2. An electronic audio replaying device, comprising:
a console;
an electronic digital logic processor operatively received by the console;
digital storage means for use in storing associated digitized audio media, the digital storage means being operatively communicated to the digital logic processor;
electronic display operatively communicated to the digital logic processor for use in displaying associated device replaying information, the electronic display being operatively received by the console;
user-interface operatively communicated to the digital logic processor for use in receiving user-input;
audio output means operatively communicated to the digital storage means;
monetary receiving means for use in receiving monetary units; the monetary receiving means being operatively communicated to the digital logic processor; and,
wherein the associated digitized audio media is transmitted through the audio output means responsive to the monetary receiving means and the user-interface.

3. The device of claim 2, wherein the console is stand alone console.

4. The device of claim 3, wherein the stand alone console has at least a first face portion, and,
wherein the electronic display and the user-interface means are operatively received by the at least a first face portion.

5. The device of claim 3, wherein the user-interface includes one or more selector buttons, and,
wherein associated device replaying information is displayed responsive to the input by way of the one or more selector buttons.

6. The device of claim 5, wherein the user-interface includes a joystick, and,
wherein associated device replaying information is displayed responsive to the input by way of the joystick.
